(19) United States
(12) Patent Application Publication
(10) Pub. No.: US 2015/0224942 A1
(43) Pub. Date: Aug. 13, 2015

(54) INTEGRATED ENTERTAINMENT DEVICE FOR VEHICLES

(71) Applicant: Sutrisno LIONO, Surabaya (ID)

(72) Inventor: Sutrisno LIONO, Surabaya (ID)

(21) Appl. No.: 14/218,260

(22) Filed: Mar. 18, 2014

(30) Foreign Application Priority Data
Feb. 12, 2014 (SG) 201401238-9

(51) Int. Cl. B60R 11/02; H03G 3/20

(52) U.S. Cl. CPC B60R 11/0217; H03G 3/20

(57) ABSTRACT

An audio device adapted to be installed in a vehicle, the device has at least one internal speaker driver, a processor adapted to receive and process a signal from at least one audio source, and adapted to at least transmit and play the processed signal through the at least one internal speaker driver, and an amplifier adapted to amplify the processed signal transmitted by the processor, wherein the at least one internal speaker driver, the processor and the amplifier are all contained in a single unit, and wherein the device is configured to fit substantially within a vehicle head unit mounting location.

### CROSS-REFERENCE TO RELATED APPLICATIONS

This application claims the benefit of Singapore Patent Application No. 201401238-9 filed on Feb. 12, 2014, the entire contents of which are incorporated herein by reference.

### FIELD OF INVENTION

The present invention relates generally to an entertainment device for use in vehicles, particularly but not limited to automobiles.

### BACKGROUND OF INVENTION

Most vehicles are equipped with an entertainment system of some description. In a typical vehicle audio system, a head unit is connected to speaker drivers located in the front and rear door panels, where the head unit is usually equipped with a media source (e.g. CD/DVD drives, radio tuner, USB etc) and a basic audio frequency tuning capability to generally adjust the low, middle and high frequency settings.

However, where the speaker drivers are located and how they are positioned within a vehicle will affect the sound quality of the audio produced. For example, if a speaker driver's box compartment's volume or depth is not suitable or the speaker driver is placed incorrectly, a humming noise may result due to a lack of or a peaking of certain frequencies. Further, an audio feedback may be created if the wall-to-wall distance in the box compartment is too short.

To improve sound quality, vehicle owners would usually change or modify their existing audio system, by replacing the head unit, installing two or three way speakers with high frequency speaker drivers or tweeters in the A pillars or the dashboard of the vehicle, and/or installing low frequency speaker drivers or sub-woofers in the rear of the vehicle together with an appropriate separate amplifier. Such modifications of the audio system and addition of speaker drivers aim to provide a wider sound stage and better sound quality of the audio played in the vehicle.

However, there are limitations to the vehicular space. Vehicle manufacturers would have to plan early in the vehicle's design in order to optimize the audio system. However, this is often neglected and not prioritized, particularly if vehicle manufacturers are operating under cost constraints, because such audio design is complicated and typically requires additional parts and wiring.

WO 2010/042285 A1 discloses a vehicle audio system where a loudspeaker, amplifier, media source, user interface, and mechanical interface are integrated into a single removable head unit having a two portions—a first portion configured to mount into a vehicle radio mounting location while a second portion configured to extend significantly outside the vehicle radio mounting location when the first portion is mounted. The head unit disclosed in WO 2010/042285 A1 is useful when the occupants of a vehicle wish to operate the head unit as an independent device outside of the vehicle or do not want it to get stolen if left in the vehicle. However, said head unit is bulky and is not integrated into the vehicle's interior front panel display when mounted into the vehicle radio mounting location. This affects the appearance and design of the vehicle's interior.

Accordingly, it is the object of the present invention to provide a device which fits substantially within a mounting location of a vehicular dashboard and enhances sound quality of the audio playback in vehicles.

### SUMMARY OF INVENTION

According to a first aspect of the invention, there is provided an audio device adapted to be installed in a vehicle, the audio device comprising at least one internal speaker driver, a processor adapted to receive and process a signal from at least one audio source, and adapted to at least transmit and play the processed signal through the at least one internal speaker driver, and an amplifier adapted to amplify the processed signal transmitted by the processor, wherein the at least one internal speaker driver, the processor and the amplifier are all contained in a single unit, and wherein the device is configured to fit substantially within a vehicle head unit mounting location.

Preferably, the vehicle head unit mounting location is a single DIN or double DIN slot.

Preferably, the processor is configurable, and adapted to analyze the signal in real-time and optimize the signal to within desired parameters. Such desired parameters include frequency optimization, gain normalization and frequency band splits. Frequency optimization includes enhancing, reducing or eliminating certain frequencies, and Q factor adjustment; gain normalization includes applying gain to a signal to bring the signal's average or peak amplitude to a targeted level, and audio compression where a signal is processed to fit within a minimum and maximum gain level; and frequency band splits includes separating or instructing an audio crossover to separate the signal based on its frequencies and sending the separated frequencies to appropriate speaker drivers.

Preferably the audio device is connectable to at least one external speaker driver located in the vehicle, and wherein the processor is adapted to at least transmit and play the processed signal through the at least one external speaker driver.

Preferably, the amplifier is a two-channel, four-channel or six-channel amplifier. It is preferable to use a two-channel amplifier in a vehicle without external speaker drivers; a four-channel amplifier in a vehicle with two external speaker drivers; a six-channel amplifier in a vehicle with four external speaker drivers.

Preferably, the at least one internal speaker driver has a central plane which forms an angle with a plane extending from the front to the back of the audio device. Preferably, the angle is less than 60°, and more preferably, the angle ranges from 45° to 55°, and even more preferably, the angle is 48.5°.

Preferably, the audio device includes a front panel with at least one outlet corresponding to the at least one internal speaker driver.

Preferably, a chamber is provided in front of the at least one internal speaker driver for directing sound waves produced by the at least one internal speaker driver toward the at least one outlet. The chamber is preferably a resonance chamber.

Preferably, the processor is a digital signal processor.

Preferably, the device has two internal speaker drivers.

Preferably, the at least one audio source communicates wirelessly with the device.

According to a second aspect of the present invention, there is provided a method for providing a car audio system in a vehicle, the method comprising installing an audio device to fit substantially within a vehicle head unit mounting location, the audio device having at least one internal speaker driver, a processor, and an amplifier; connecting the audio device to at least one external speaker driver located in the vehicle, wherein the processor is adapted to receive and process a signal from at least one audio source, and adapted to transmit and play the processed signal through the at least one internal and external speaker drivers, and wherein the amplifier is adapted to amplify the processed signal transmitted by the processor.

From the foregoing disclosure and the following more detailed description of various embodiments it will be apparent to those skilled in the art that the present invention provides a significant advance in the technology of audio systems for use in vehicles. It is particularly significant that the present invention provides an installable device which fits substantially into a vehicle head unit mounting location where the device is capable of providing high quality audio playback in vehicles. Additional features and advantages of various embodiments will be better understood in view of the detailed description provided below.

### BRIEF DESCRIPTION OF THE DRAWINGS

The present invention will now be described, by way of example only, with reference to the accompanying drawings.

FIG. 1 is perspective view of a first embodiment of the present invention.

FIG. 2 is a partially exploded view of the first embodiment of FIG. 1 with the top of the speaker housings removed.

FIG. 3 is a top view of the first embodiment of FIG. 1 with the top of speaker housings removed.

FIG. 4 is a front view of the first embodiment of FIG. 1 where a portion of the front panel is removed to reveal the placement of the speaker driver behind the front panel.

FIG. 5 is a side view of the first embodiment of FIG. 1 installed within a head unit mounting location of a vehicle's dashboard.

FIG. 6 is a perspective view of a second embodiment of the present invention.

FIG. 7 is a partially exploded view of the second embodiment of FIG. 6 with the top of speaker housings removed.

FIG. 8 is a perspective view of the speaker housings of the second embodiment of FIG. 6.

FIG. 9 is a top view of the speaker housings of the second embodiment of FIG. 6 with the top removed.

FIG. 10 is front view of the second embodiment of FIG. 6 where a portion of the front panel is removed to reveal the placement of the speaker driver behind the front panel.

FIG. 11 is a side view of the second embodiment of FIG. 6 installed within a head unit mounting location of a vehicle's dashboard.

FIG. 12 is a perspective view of a third embodiment of the present invention.

FIG. 13 is a partially exploded view of the third embodiment of FIG. 12 with the top of the speaker housings removed.

FIG. 14 is a front view of the third embodiment of FIG. 12 where a portion of the front panel is removed to reveal the placement of the speaker driver behind the front panel.

FIG. 15 is a side view of the third embodiment of FIG. 12 installed within a head unit mounting location of a vehicle's dashboard.

FIG. 16 is a schematic diagram of how the processor, in particular the digital signal processor (DSP) of the present invention functions.

It should be understood that the drawings are not necessarily to scale. The drawings simply present a representation of the features involved in the working of the present invention. The specific dimensions of the present invention may be determined in part by the particular intended application and use environment, for example, the size of the speaker drivers depend on the placement angle of said speaker drivers within the speaker housings.

### DETAILED DESCRIPTION OF THE DRAWINGS

It will be apparent to those skilled in the art, that is, to those who have knowledge or experience in this area of technology that many uses and design variations are possible for the device disclosed here. The following detailed discussion of various alternate features and embodiments will illustrate the general principles of the invention with reference to a device suitable for use in vehicles. Other embodiments suitable for other applications will be apparent to those skilled in the art given the benefit of this disclosure. It will be understood that the embodiments described are intended to be illustrative of the general inventive concept, and not limitative thereof.

In the present disclosure, any depiction of a given element or use of a particular element number in a particular figure or a reference thereto in corresponding descriptive material, can encompass the same, an equivalent, or an analogous element or element number indicated or identified in another figure or descriptive material associated therewith.

For the purposes of the description and the claims, the term “real-time” refers to, corresponds with or is defined as the time during which a signal is being received, processed and/or transmitted by the processor.

It will be understood by those skilled in the art that, in general terms, a speaker driver is a transducer that converts electrical energy to sound energy. A speaker driver may be a high, mid, low or a full-range frequency speaker driver. A tweeter or a high frequency driver may generate sound over a range of about 4000 Hz to about 20 kHz and above; a mid-range or mid-bass frequency driver may generate sound over a range of about 150 Hz to about 4000 Hz; a woofer or low frequency driver may generate sound over a range of about 20 Hz to about 150 Hz; and a full-range speaker may generate sound over the entire audible frequency range of 20 Hz to 20 KHz. Generally, all the frequencies are in a range audible to humans, and the frequency ranges of the tweeter, mid-range driver and woofer may overlap. Of course, the precise limits of these ranges may be varied from component to component, as would be understood by those skilled in the art.

It will also be understood by those skilled in the art that, in general terms, a processor is a device which can process signals, in the digital or analog domain, from digital to analog or vice versa, and such processing includes alteration, manipulation and conversion of characteristics of the signal being processed. A digital signal processor (DSP) is a processor which mathematically manipulates and processes digital signals, and it has the architecture which is optimized for the fast operational needs of digital signal processing. A DSP may be programmable, and it can be a single component or made up of multiple components.

Further, it will be understood by those skilled in the art that a vehicle head unit mounting location may be a single DIN slot, a double DIN slot or any suitable slot in a vehicle's dashboard. In general terms, it will be understood that a single DIN slot has a panel which measures 180 mm (width) by 50 mm (height) while a double DIN slot has a panel which measures 200 mm or 180 mm (width) by 100 mm (height). A single DIN slot could also have a panel which measures 7 inches (width) by 2 inches (height) and a double DIN slot could also have a panel which measures 7 inches (width) by 3.5 inches or 4 inches (height).

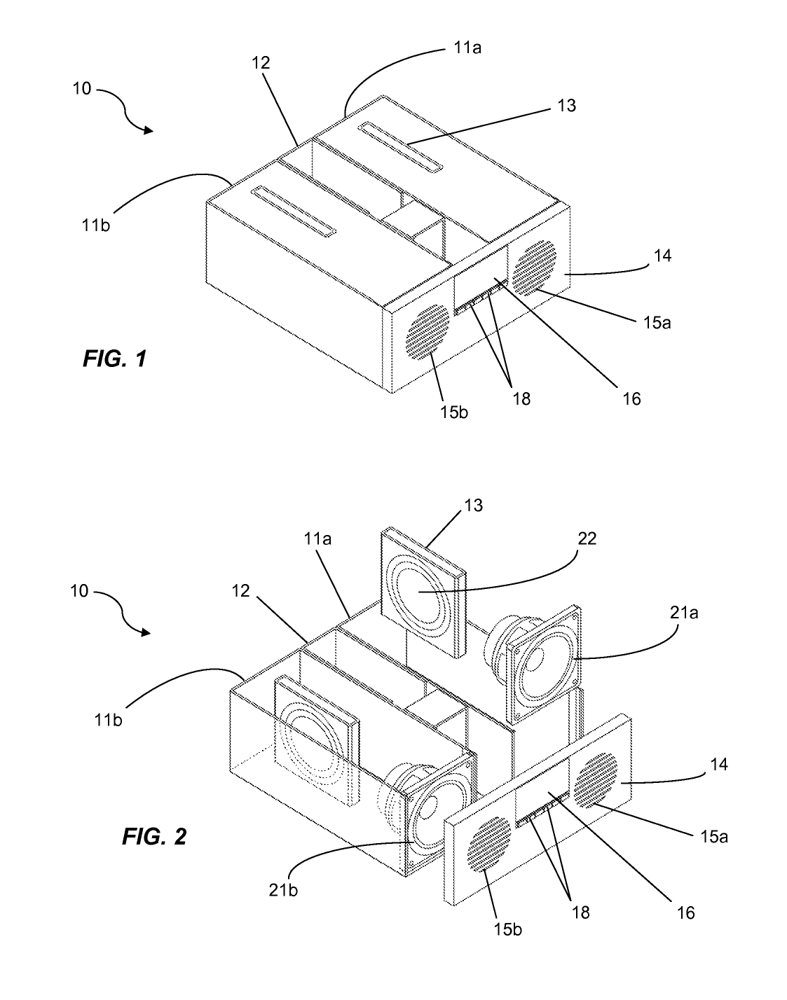

Turning now to the drawings, FIGS. 1 to 5 show a first embodiment of the present invention. Device 10 is suitable for installation in a single DIN slot of a vehicle. While not shown, device 10 may include suitable fastening means such as brackets and screw holes for installation in a single DIN slot. Device 10 comprises speaker housings 11a,b which are separated by an electronics housing 12. Each speaker housing 11a,b has a frame 13. It would be understood that each speaker housing 11a,b may have internal compartments to separate the housing components. A front panel 14 is provided at the front of device 10 with outlets 15a,b, a light-emitting diode (LED) display 16 and buttons 18.

Electronics housing 12 houses the electronics which control the operation of device 10, and said housing includes a processor and amplifier. The electronics housing 12 may also include a Global Positioning System (GPS) receiver. An audio source may be located within device 10, but may or may not be housed within electronics housing 12. Alternatively, the audio source may be located external to device 10 where said music source can be in wired connection with or be connected wirelessly to the electronics in electronic housing 12 for device 10 to function. Audio sources can include CD/DVD drives, portable media players, hard disk drives, flash memory drives, radio tuners, audio cassettes and microphones. If the audio source is connected wirelessly to device 10, said audio source may communicate with device 10 via, for example, a WIFI or Bluetooth connection. It will be understood that electronics housing 12 may include other electronics depending on the use environment of the present invention and should not be limited to the electronics described herein.

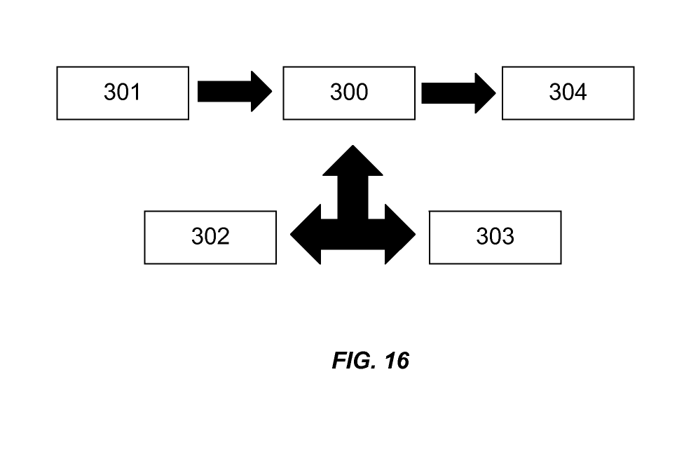

The processor is preferably a DSP. With reference to FIG. 16, an audio signal is received at the digital audio input 301 and transmitted to the DSP 300. Sound profiles with pre-programmed parameter settings are saved on integrated circuit electrically erasable programmable read-only memory (IC EEPROM) 303, which is in electrical communication with DSP 300. The DSP 300 will analyze the audio signal in real-time from the digital audio input 301 and optimize it for playback based on the pre-programmed parameter settings on the IC EEPROM 303. The processed audio signal is then transmitted to the digital audio output 304 and out to the amplifier for amplification before reaching the speaker drivers. A controller 302 is also in electrical communication with DSP 300 and IC EEPROM 303. The controller 302 provides certain adjustment capabilities (for example phase shifts adjustments) and allows for the selection of the sound profiles by the occupants of the vehicle.

Depending on the sound profile selected, the DSP 300 will alter and manipulate the audio signal differently. The DSP 300 can extend the frequency response of all speaker drivers which device 10 is connected to, including speaker drivers 21a,b, and maximize the frequency-specific power distribution of the amplifier. For example, the DSP 300 may have several frequency filters where certain frequencies are enhanced, eliminated or reduced. The DSP 300 can also alter the attack time of an automatic gain control and control the band-split frequency edges of an audio crossover.

The DSP 300 and IC EEPROM 303 are configurable to the vehicle's environment and the entire audio system (if there are external speaker drivers installed within the vehicle) in order to optimize the processing of the audio signal from the audio source. To configure DSP 300 and IC EEPROM 303, pink noise is first transmitted through device 10 and a frequency response profile is obtained from the speaker drivers connected to device 10. A computer (not shown) is connected to IC EEPROM 303, where appropriate software may be used to adjust the sound parameters on DSP 300 to suit the vehicle's environment. The settings of adjusted sound parameters are then saved as a sound profile on IC EEPROM 303.

Device 10 may be operated via controller 302 manually by buttons 18 or wirelessly via a remote control (not shown). Information such as the title of the song being played and the pre-programmed settings of the device 10 are displayed on LED display 16.

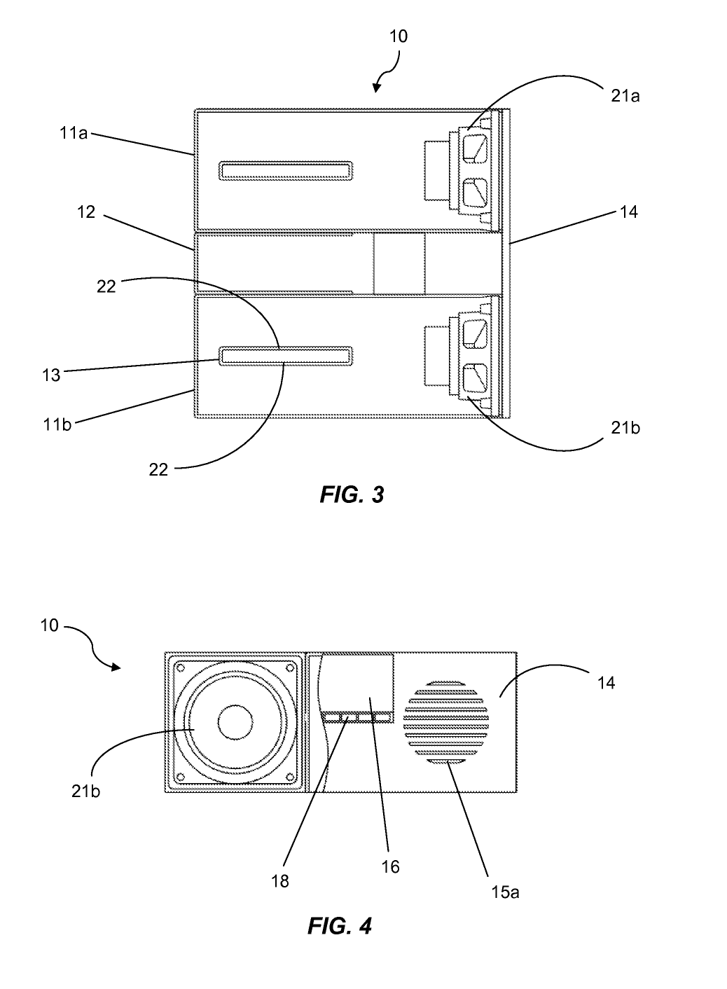

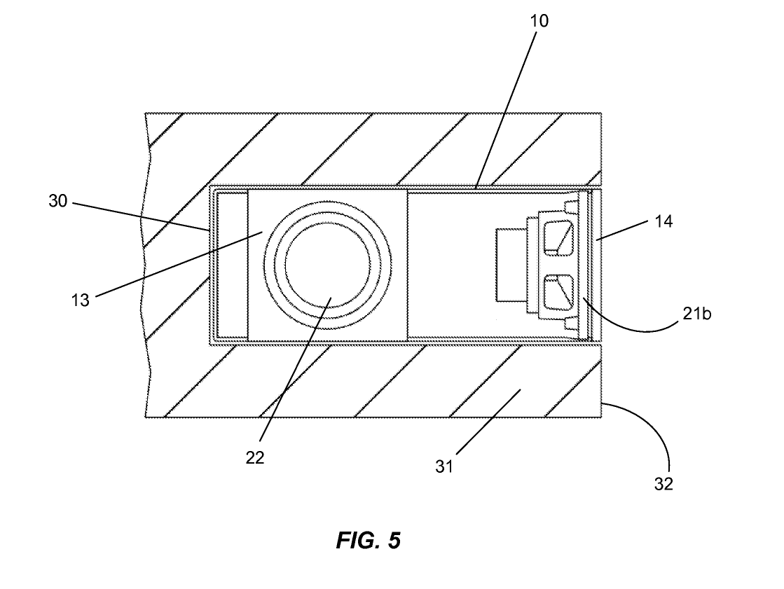

As shown in FIGS. 2 and 3, speaker drivers 21a,b are located within the speaker housing 11a,b—one speaker housing 11a,b houses one speaker driver 21a,b. The speaker drivers 21a,b may be high, mid, low or full-range speaker drivers. FIGS. 3 and 4 show that the speaker drivers 21a,b are front facing where the front of the speaker drivers 21a,b are substantially parallel to the front of the device 10. Outlet 15a corresponds to speaker driver 21a while outlet 15b corresponds to speaker driver 21b. Outlets 15a,b may suitably have a grille, a mesh or may not be covered so long as it does not substantially hinder sound waves produced by the speaker drivers 21a,b from reaching occupants of the vehicle where device 10 has been installed.

Passive radiators 22 are located on each side of frame 13. Frame 13 is positioned vertically and the diaphragms of passive radiators 22 face the sides of the speaker housings 11a,b when device 10 is installed within a single DIN slot 30 of a vehicle. The diameter of passive radiators 22 may or may not be equal to the length of each side of frame 13, so long as each passive radiator 22 is able to fit within the side of frame 13 on which it is located. For optimal performance of passive radiators 22, speaker housings 11a,b are preferably air-tight. It would be understood that the inclusion of passive radiators 22 and frame 13 in device 10 is optional and may accordingly be omitted depending on the use environment.

As shown in FIG. 5, when the device 10 is installed within a single DIN slot 30 of a vehicle's dashboard 31, the device 10 fits substantially within the single DIN slot 30 where the surface of front panel 14 may or may not be substantially continuous with the surface of the front 32 of dashboard 31. As device 10 fits substantially within the single DIN slot 30 when installed, device 10 will not hinder the normal operations of the vehicle. Further, when device 10 fits substantially within the single DIN slot 30, it conforms to the appearance or interior design of the vehicle.

If device 10 is installed within a vehicle without an existing audio system, device 10 is capable of acting as a standalone integrated audio system which provides audio playback through its internal speaker drivers 21a,b to occupants in the vehicle. The position of the speaker drivers 21a,b in the device 10 and the position of device 10 itself when said device is installed, provides an optimal center audio image and sound stage.

However, if there are speaker drivers located in other positions in the vehicle, for example in the front and rear door panels, device 10 may be electronically connected to these speaker drivers. When device 10 is connected to such speaker drivers, device 10 controls and cooperates with these speaker drivers, together with speaker drivers 21a,b, to provide audio playback in the vehicle. The number of channels which the amplifier (housed within electronics housing 12) has, depends on the total number of speaker drivers which device 10 is in connection with and controls. For example, if the vehicle has four speaker drivers, one installed in each of the vehicle's door panels, the amplifier in device 10 will have at least six channels—two channels for the speaker drivers 21a,b and four for the external speaker drivers located in the door panels. When the device 10 is connected to speaker drivers distributed in other parts of the vehicle, the processor can receive a signal from the audio source, process said signal and transmit the processed signal via the amplifier to all of the speaker drivers, including speaker drivers 21a,b. It would be understood that the device 10 may also connect and control an external amplifier which powers speaker drivers distributed around the vehicle. In such an arrangement, the processor can transmit the processed signal to the speaker drivers distributed around the vehicle via the external amplifier, while at the same time, transmit the processed signal to the speaker drivers 21a,b via the internal amplifier located in device 10.

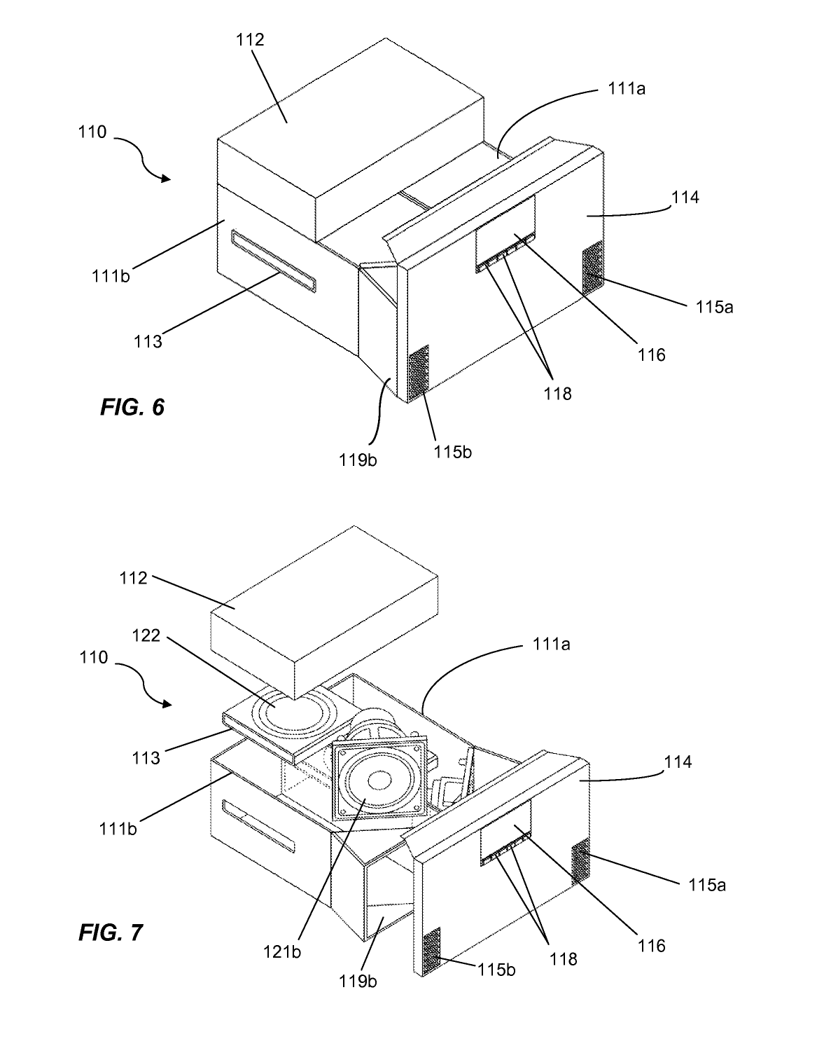

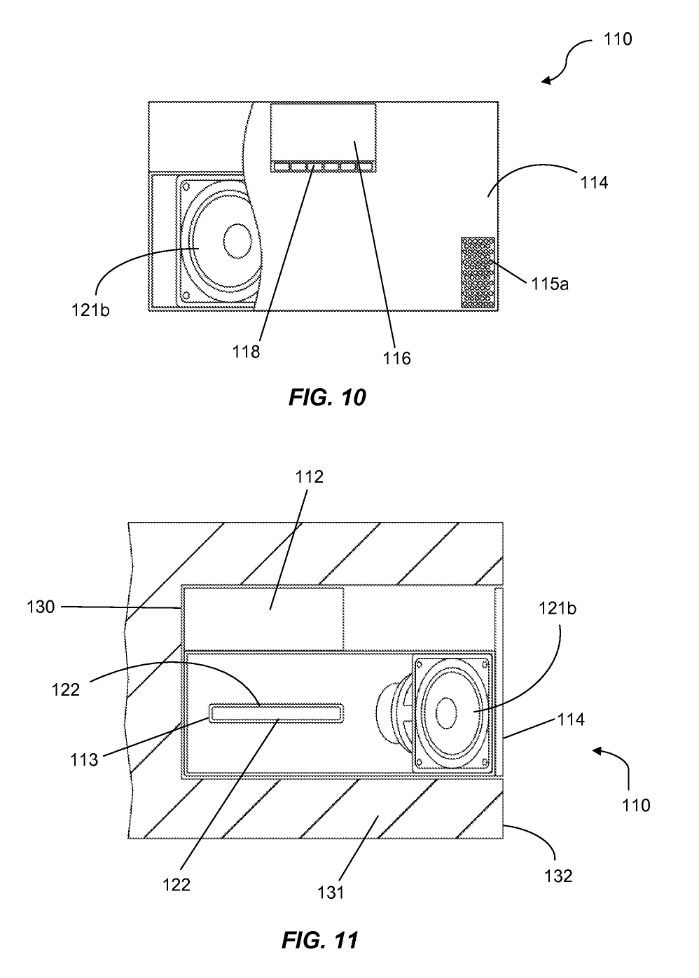

FIGS. 6 to 11 show a second embodiment of the present invention. Device 110 is suitable for installation in a double DIN slot 130 of a vehicle. In device 110, the speaker housings 111a,b are located adjacent one another. In such a configuration, while the speaker housings 111a,b disclosed herein are separate housings, with each housing one speaker driver 121a,b, it would be understood that the two speaker housings 111a,b may be a single housing which housing two speaker drivers 121a,b. Electronics housing 112 is located on top of the speaker housings 111a,b when device 110 is installed in a normal mounting position as shown in FIG. 11. However, it would be understood that the electronic housing 112 may also be located below the speaker housings 111a,b when device 110 is installed in a normal mounting position. Each speaker housing 111a,b also includes a frame 113 where passive radiators 122 are located. LED display 116, buttons 118 and outlets 115a,b are located on front panel 114. Outlets 115a,b correspond to speaker drivers 121a,b accordingly. Electronics housing 112 houses the electronics which operate device 110 in a similar manner as the first embodiment of the present invention.

As shown in FIGS. 7 and 11, frame 113 is positioned horizontally and the diaphragms of passive radiators 122 face the top and bottom of the speaker housings 111a,b when device 110 is installed within a double DIN slot of a vehicle.

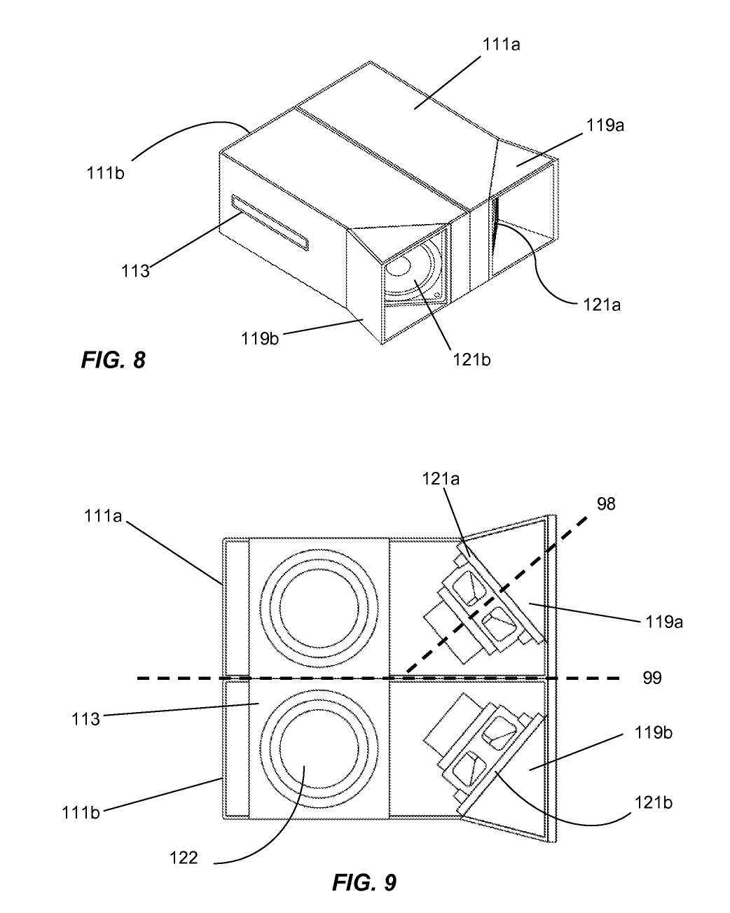

FIGS. 8 and 9 provide greater detail of the speaker housings 111a,b. In FIG. 9, each speaker driver 121a,b has a central plane 98 running from the front to the rear of the speaker driver 121a,b. A plane 99 is also provided between the speaker housings 111a,b, which runs from the front to the rear of device 110. Central plane 98 is at an angle to plane 99, where the angle is less than 60°, and more preferably, the angle ranges from 45° to 55°, and the preferred angle is 48.5°. When the speaker drivers are not angled (i.e. at 0°), the fronts of the speaker drivers 121a,b are substantially parallel to the front of device 110. When the angle is more than 0°, the speaker drivers 121a,b provide a wider sound stage for the audio playback in the vehicle because they are angled away from the plane 99. This improves the directivity in the sound waves produced by speaker drivers 121a,b towards occupants of the vehicle, particularly the driver and the front seat passenger. Further, having speaker drivers 121a,b at an angle, allows installation in speaker housings 111a,b, of speaker drivers with a larger diameter since the angle will provide more space for installation within each speaker housing 111a,b. A chamber 119a,b is located in front of each speaker driver 121a,b. Sound waves produced by the speaker drivers 121a,b are directed by the walls of the chamber 119a,b towards the outlets 115a,b. Chambers 119a,b can also act as resonance chambers which amplifies the sounds waves as a whole or only certain frequencies of the sound waves produced by the speaker drivers 121a,b.

When device 110 is installed within the double DIN slot 130 of the dashboard 131 a vehicle, said device fits substantially within the double DIN slot 130 as shown in FIG. 11. The surface of front panel 114 will be substantially continuous with the surface of the front 132 of dashboard 131 when device 110 is installed. Device 110 may be connected to other speaker drivers located in other parts of the vehicle, to control and cooperate with these speaker drivers to provide audio playback in the vehicle.

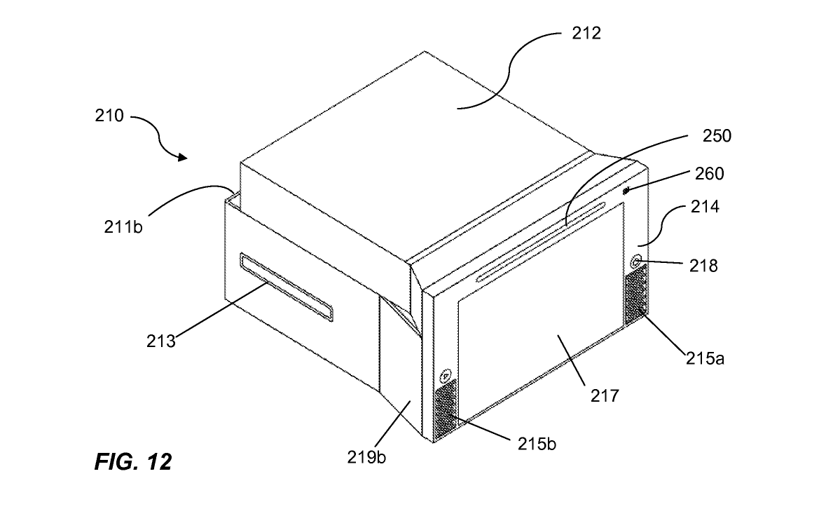

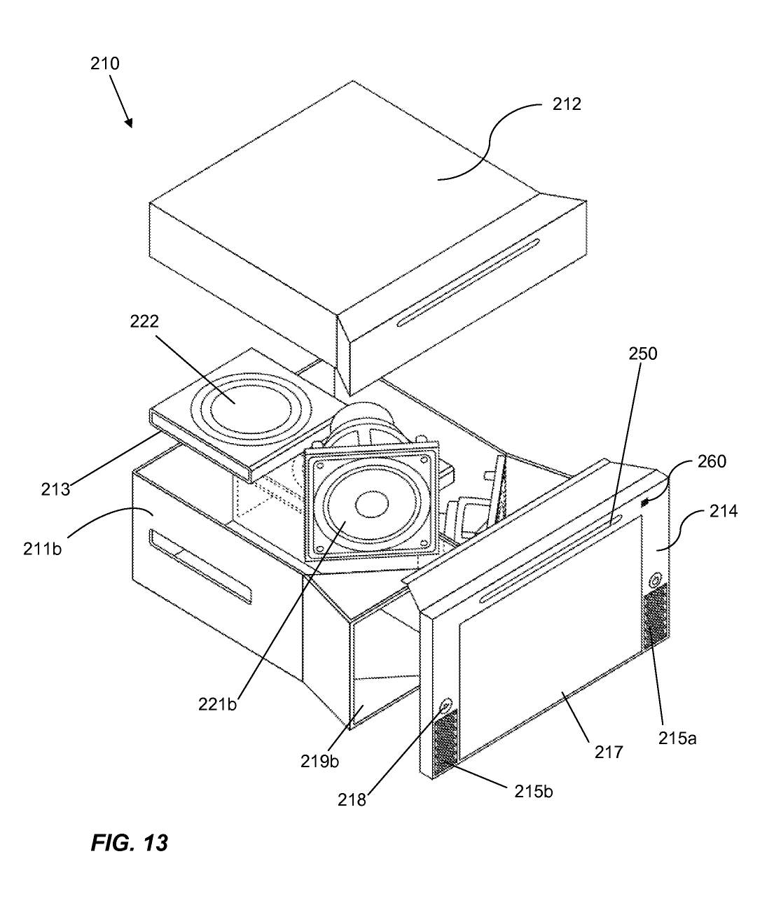

FIGS. 12 to 15 show a third embodiment of the present invention. Like the second embodiment, the speaker housings 211a,b are located adjacent one another with the electronics housing 212 located above the speaker housings 211a,b. In this third embodiment, electronics housing 212 includes a CD/DVD drive 250 and the front panel 214 includes a microphone 260 and a liquid crystal display (LCD) 217. The microphone 260 may be an additional alternative audio source for device 210. The positioning of the speaker drivers 221a,b within speaker housings 211a,b is the same as that of the speaker drivers 121a,b in the second embodiment (see FIGS. 6 to 11).

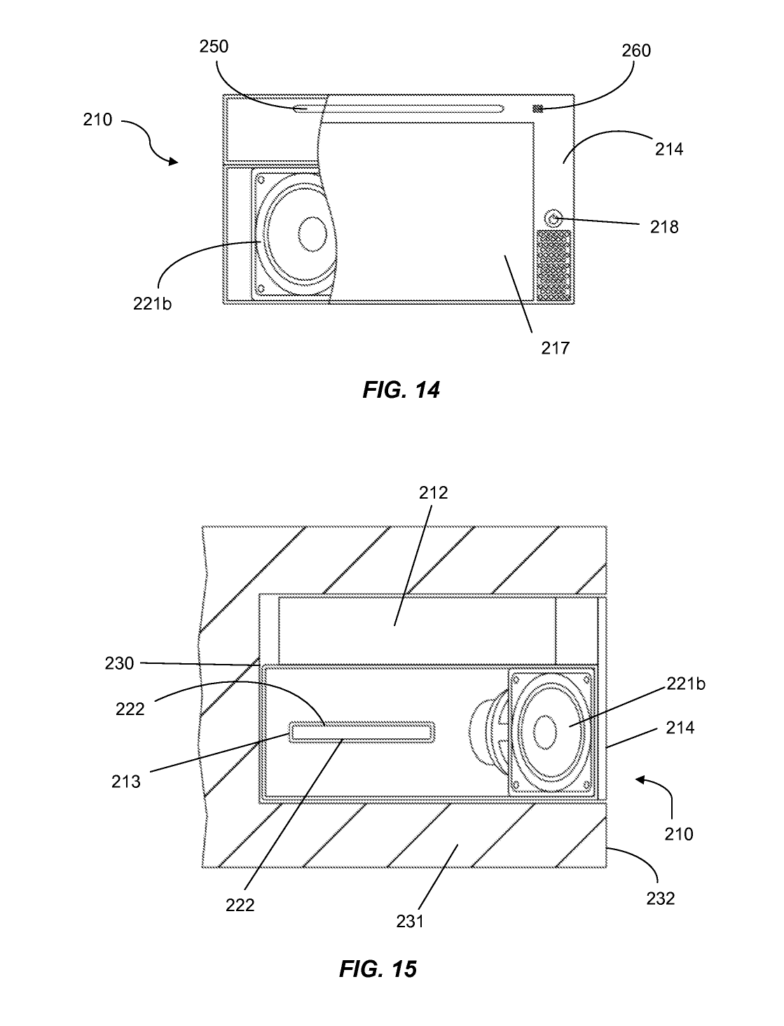

Device 210 fits substantially within the double DIN slot 230 as shown in FIG. 15, when said device is installed. Similarly, the surface of front panel 214 will be substantially continuous with the surface of the front 232 of dashboard 231 when device 210 is installed. Device 210 may be connected to other speaker drivers located in other parts of the vehicle, to control and cooperate with these speaker drivers to provide audio playback in the vehicle.

From the foregoing disclosure and detailed description of certain embodiments, it will be apparent that various modifications, additions and other alternative embodiments are possible without departing from the true scope and spirit of the invention. The embodiments discussed were chosen and described to provide the best illustration of the principles of the invention and its practical application to thereby enable one of ordinary skill in the art to use the invention in various embodiments and with various modifications as are suited to the particular use contemplated. All such modifications and variations are within the scope of the invention as determined by the appended claims when interpreted in accordance with the breadth to which they are fairly, legally, and equitably entitled.

1. An audio device adapted to be installed in a vehicle, the device comprising:
At least one internal speaker driver,
A processor adapted to receive and process a signal from at least one audio source, and adapted to at least transmit and play the processed signal through the at least one internal speaker driver, and
An amplifier adapted to amplify the processed signal transmitted by the processor,
wherein the at least one internal speaker driver, the processor and the amplifier are all contained in a single unit, and wherein the device is configured to fit substantially within a vehicle head unit mounting location.

2. The audio device of claim 1 wherein the vehicle head unit mounting location is a single DIN or double DIN slot.

3. The audio device according to claim 2, wherein the processor is configurable, and adapted to analyze the signal in real-time and optimize the signal to within desired parameters.

4. The audio device according to claim 3, wherein the desired parameters include frequency optimization, gain normalization and frequency band splits.

5. The audio device according to claim 3, wherein the audio device is connectable to at least one external speaker driver located in the vehicle, and wherein the processor is adapted to at least transmit and play the processed signal through the at least one external speaker driver.

6. The audio device according to claim 1, wherein the amplifier is a two-channel, four-channel or six-channel amplifier.

7. The audio device according to claim 1, wherein the at least one internal speaker driver has a central plane which forms an angle with a plane extending from the front to the back of the audio device.

8. The audio device according claim 7, wherein the angle is less than 60°.

9. The audio device according to claim 8, wherein the angle ranges from 45° to 55°.

10. The audio device according to claim 1, wherein the audio device includes a front panel with at least one outlet corresponding to the at least one internal speaker driver.

11. The audio device according to claim 10, wherein a chamber is provided in front of the at least one internal speaker driver for directing sound waves produced by the at least one internal speaker driver toward the at least one outlet.

12. The audio device according to claim 11, wherein the chamber is a resonance chamber.

13. The audio device according to claim 1, wherein the processor is a digital signal processor.

14. The audio device according to claim 1, the audio device having two internal speaker drivers.

15. The audio device according to claim 1, wherein the at least one audio source communicates wirelessly with the audio device.

16. A method for providing a car audio system in a vehicle, the method comprising:
Installing an audio device to fit substantially within a vehicle head unit mounting location, the audio device having:
At least one internal speaker driver;
A processor; and
An amplifier,
connecting the audio device to at least one external speaker driver located in the vehicle,
wherein the processor is adapted to receive and process a signal from at least one audio source, and adapted to transmit and play the processed signal through the at least one internal and external speaker drivers, and wherein the amplifier is adapted to amplify the processed signal transmitted by the processor.

17. The method of claim 16, wherein the vehicle head unit mounting location is a single DIN or double DIN slot.

18. The method according to claim 17, wherein the processor is configurable, and adapted to analyze the signal in real-time and optimize the signal to within desired parameters.

19. The method according to claim 18, wherein the desired parameters include frequency optimization, gain normalization and frequency band splits.

20. The method according to claim 16, wherein the amplifier is a two-channel, four-channel or six-channel amplifier.

21. The method according to claim 16, wherein the at least one internal speaker driver has a central plane which forms an angle with a plane extending from the front to the back of the audio device

22. The method according to claim 21, wherein the angle is less than 60°.

23. The method according to claim 22, wherein the angle ranges from 45° to 55°.

24. The method according to claim 16, further providing a front panel with at least one outlet corresponding to the at least one internal speaker driver.

25. The method according to claim 24, further providing a chamber in front of the at least one internal speaker driver for directing sound waves produced by the at least one internal speaker driver toward the at least one outlet.

26. The method according to claim 25, wherein the chamber is a resonance chamber.

27. The method according to claim 16, wherein the processor is a digital signal processor.

28. The method according to claim 16, the audio device having two internal speaker drivers.

29. The method according to claim 16, wherein the at least one audio source communicates wirelessly with the audio device.
